(19) United States
(12) Patent Application Publication
(10) Pub. No.: US 2018/0231828 A1
(43) Pub. Date: Aug. 16, 2018

(54) INDIUM TIN OXIDE THIN FILM AND PREPARATION METHOD THEREOF, ARRAY SUBSTRATE AND DISPLAY APPARATUS COMPRISING THE SAME

(71) Applicants: BOE TECHNOLOGY GROUP CO., LTD., Beijing (CN); HEFEI BOE DISPLAY LIGHTING CO., LTD., Xinzhan Park (CN)

(72) Inventors: Qiping Zhang, Beijing (CN); Wenbo Sun, Beijing (CN); Yejia Qian, Beijing (CN)

(21) Appl. No.: 15/551,035

(22) PCT Filed: Feb. 24, 2017
(86) PCT No.: PCT/CN2017/074765

§ 371 Date: Aug. 14, 2017

(30) Foreign Application Priority Data
Jul. 12, 2016 (CN) 201610545577.X

(51) Int. Cl. G02F 1/1335; C23C 14/35; C23C 14/08; H01L 27/12; H01L 29/786

(52) U.S. Cl. CPC G02F 1/133514; C23C 14/35; H01L 29/786; H01L 27/12; C23C 14/08

(57) ABSTRACT

An indium tin oxide thin film and a preparation method thereof, an array substrate and a display apparatus comprising this indium tin oxide thin film. Here, the preparation method for this indium tin oxide thin film comprises: providing an indium oxide target material, a tin target material, and a matrix, which are discrete, in a depositing chamber; generating oxygen particles and indium particles from a target surface of the indium oxide target material while generating tin particles from a target surface of the tin target material; and depositing the oxygen particles, the indium particles, and the tin particles on the surface of the matrix to form the indium tin oxide thin film.

### CROSS-REFERENCE TO RELATED APPLICATION

This application claims the priority of Chinese Patent Application 201610545577.X filed on Jul. 12, 2016, and entitled “Indium Tin Oxide Thin-Film and Preparation Method Thereof, Array Substrate and Display Apparatus Comprising the Same”, which is incorporated herein by reference in its entirety.

### TECHNICAL FIELD

This disclosure relates to the technical fields of display and thin film deposition, and particularly to an indium tin oxide thin film and a preparation method for this indium tin oxide thin film, an array substrate and a display apparatus comprising the indium tin oxide thin film.

### BACKGROUND ART

The production of a thin film transistor liquid crystal panel mainly comprises three stages, which are an array process, an assembly process, and a module process. In the array process, a layer of a metal film is first plated on a clean glass substrate by using a sputtering apparatus, and a nonconductive layer and a semiconductor layer are next plated, wherein the semiconductor layers are often transparent conductive oxide thin films, among which an indium tin oxide (ITO) thin film is the most widely used. ITO thin films having different component proportions exhibit differences in photoelectric properties, such as transmittance, carrier mobility, dislocation density, etc. In existing liquid crystal displays, the preparation of ITO thin films is mainly achieved in a manner of magnetron sputtering.

As consumers have increasing requirements for the effect of display, the studies on photoelectric properties of indium tin oxide thin-films, for example studies on properties of indium tin oxide thin-films having different tin contents, by the academic world have continuously deepened. In the prior art, in order for the preparation and study of ITO thin films having specific tin contents, it is necessary to prepare indium oxide and tin oxide according to a proportion, then treat the powders by mixing, grinding, and fining, and further press, pre-sinter, polish, sinter, and polish the treated powders to produce an ITO target material having a specific component proportion, and then put the ITO target material in a magnetron sputtering apparatus and produce an indium tin oxide thin film sample having a desired thickness by sputtering with the apparatus, which sample is subjected to further study. However, if a certain property parameter of the sample prepared is not good and it is required to be further adjusted by composition proportioning, the target material produced has a very rare possibility for reuse and is almost required to be wasted, and the oxide powders are required to be re-proportionated, re-sintered, and polished to be re-prepared into a new target material for experiments. It is difficult to effectively control time waste and economic waste caused by this process. Meanwhile, since the vacuum sputtering chamber of the apparatus has been opened several times, the useful life of the magnetron sputtering apparatus is also reduced and it fails to effectively control the loss of the apparatus.

### SUMMARY

According to an aspect of the present invention, there is provided a preparation method for an indium tin oxide thin film, comprising:

providing an indium oxide target material, a tin target material, and a matrix, which are discrete, in a depositing chamber;

generating oxygen particles and indium particles from a target surface of the indium oxide target material while generating tin particles from a target surface of the tin target material; and

depositing the oxygen particles, the indium particles, and the tin particles on a surface of the matrix to form an indium tin oxide thin film.

Preferably, oxygen particles and indium particles are generated from the target surface of the indium oxide target material while tin particles are generated from the target surface of the tin target material by magnetron sputtering, pulsed laser deposition, evaporation, arc plasma coating, or molecular beam epitaxy.

Preferably, the magnetron sputtering comprises dual magnetron sputtering.

Preferably, tin content in the indium tin oxide thin film is adjusted by adjusting working power P1 loaded to the indium oxide target material and/or working power P2 loaded to the tin target material.

Preferably, the working power P1 loaded to the indium oxide target material and the working power P2 loaded to the tin target material satisfies P1/P2=10:1-20:1 and P1 is greater than the sputtering threshold of the indium oxide target material and P2 is greater than the sputtering threshold of the tin target material.

Preferably, the pulsed laser deposition comprises dual pulsed laser deposition; and tin content in the indium tin oxide thin film is adjusted by adjusting power P1′ of laser irradiating the indium oxide target material and/or power P2′ of laser irradiating the tin target material.

Preferably, tin content in the indium tin oxide thin film is adjusted by adjusting the area of the target surface of the indium oxide target material and/or the area of the target surface of the tin target material.

Preferably, the matrix is heated to a temperature between 100° C. and 250° C. during deposition.

Preferably, the indium oxide target material and the tin target material are provided on the same side of the matrix; wherein the included angle between the target surface of the indium oxide target material and the surface of the matrix is α, the included angle between the target surface of the tin target material and the surface of the matrix is β, wherein 0°<α<60° and 0°<β<60°.

Preferably, the target surface of the indium oxide target material and the target surface of the tin target material are symmetrically provided relative to a perpendicular bisector of the matrix; wherein the perpendicular bisector passes through the center point of the surface of the matrix and is perpendicular to the surface of the matrix.

Preferably, the indium oxide target material and the tin target material are set to rotate with a perpendicular bisector of the matrix as an axis, and the relative positions of the target surface of the indium oxide target material and the target surface of the tin target material are kept fixed during rotation, wherein the perpendicular bisector passes through the center point of the surface of the matrix and is perpendicular to the surface of the matrix.

Preferably, the rotation has a rotation speed set to be 5-30 revolutions/minute.

Preferably, the indium oxide target material is a doped target material doped with a preset element.

Preferably, the preset element comprises one or more magnetic elements, wherein doping proportions of the one or more magnetic elements are between 0.5% and 2.5% based on the total weight of the doped target material; or the preset element comprises one or more metal elements, wherein doping proportions of the one or more metal elements are between 1% and 5% based on the total weight of the doped target material.

Preferably, a discrete doping element target material is further provided in the depositing chamber; and

doping element particles are generated from the doping element target material, and form a doped indium tin oxide thin film on the surface of the matrix together with the oxygen particles, the indium particles, and the tin particles.

Preferably, the indium oxide target material is prepared in a manner of metal oxide sintering, and the tin target material is prepared in a manner of powder metallurgy.

According to another aspect of the present invention, there is provided an indium tin oxide thin film obtained according to the preparation method described above.

According to still another aspect of the present invention, there is provided an array substrate comprising the indium tin oxide thin film described above.

Preferably, the array substrate further comprises: a substrate; and a gate line and gate electrode layer, a gate insulating layer, and an active layer, which are sequentially deposited on the substrate; wherein the substrate, on which the gate line and gate electrode layer, the gate insulating layer, and the active layer have been deposited, is used as a matrix, and the indium tin oxide thin film is deposited on the matrix.

According to yet another aspect of the present invention, there is provided a display apparatus comprising the array substrate described above.

### BRIEF DESCRIPTION OF DRAWINGS

FIG. 1 is a principle diagram of magnetron sputtering;

FIG. 2 is a process flow chart of a preparation method for an indium tin oxide thin film in an embodiment of the present invention;

FIG. 3 is a schematic diagram of the distribution of an indium oxide target material, a tin target material, and a matrix in an embodiment of the present invention;

FIG. 4 is a schematic principle diagram of the distribution of oxygen particles/indium particles and tin particles on the surface of a matrix in an embodiment of the present invention;

FIG. 5A is a flow chart of a preparation process of a target material in an embodiment of the present invention; FIG. 5B is a flow chart of a conventional preparation process of a target material;

FIG. 6 is a schematic principle diagram of a preparation method for an indium tin oxide thin film in an embodiment of the present invention; and

FIG. 7 is a schematic stereogram of the rotation of an indium oxide target material and a tin target material in an embodiment of the present invention.

### DETAILED DESCRIPTION OF EMBODIMENTS

Hereafter, the technical solutions in embodiments of the present invention will be further specifically illustrated by embodiments in conjunction with accompanying drawings. In the specification, the same or similar reference numerals indicate the same or similar members. It is to be noted that all of the accompanying drawings below are simplified schematic diagrams, and the number, shape, and size of the components in the accompanying drawings may be arbitrarily changed according to practical conditions of implementation and the layout state of the components may be more complicated. The present invention may also be implemented and applied through other different specific embodiments, and various details in this specification may also be subjected to various modifications and alterations without departing from the spirit of the present invention based on different standpoints and applications.

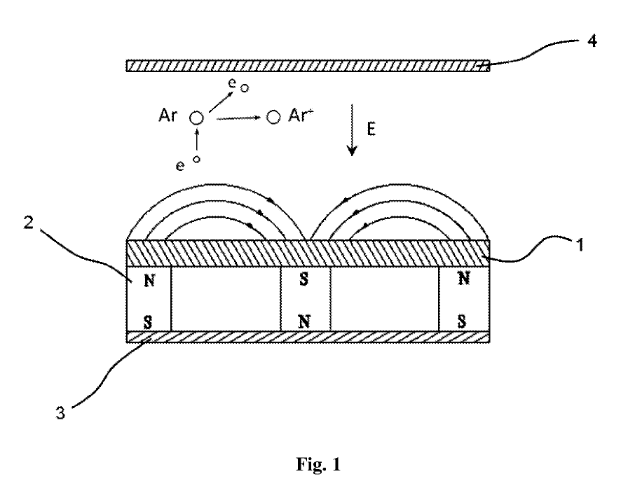

The principle of the magnetron sputtering technique is as shown in FIG. 1, in which 1—target material, 2—magnetic core, 3—target material substrate, and 4—matrix. An electron e is subjected to an accelerated motion under the action of an externally applied electric field E, and collides with an argon (Ar) atom in a vacuum chamber in the process of flying to a matrix 4, resulting in ionization of argon atom, so as to generate a positively charged argon ion (Ar⁺) and a new electron e. The new electron e flies to the matrix 4 (or collides with an Ar atom), while Ar⁺ is accelerated to fly to a target material 1 under the action of the electric field E. High-energy Ar⁺ enables particles (atoms or ions) in the target material 1 to be sputtered out and fly to the surface of the matrix 4 to form a thin film.

According to the general inventive concept of the present invention, there may be provided a preparation method for an indium tin oxide thin film, comprising using an indium oxide target material and a tin target material which are discrete, adjusting the atomic proportions of respective components in an indium tin oxide thin film by respectively controlling the deposition of particles derived from two target materials, and correspondingly adjusting thin film photoelectric properties or magnetic properties of the indium tin oxide thin film. Furthermore, repeated preparation of target materials may be avoided, and the sputtering process is not required to be restarted (for example, the vacuum chamber is not required to be re-opened halfway).

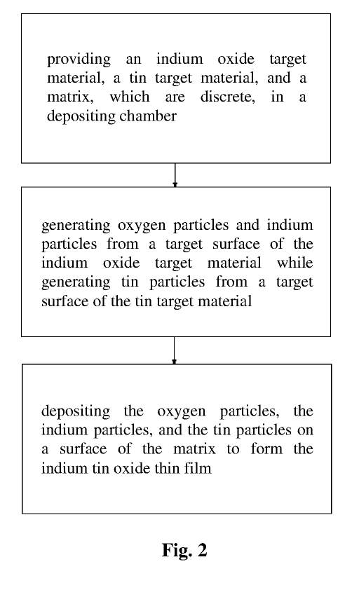

FIG. 2 is a process flow chart of a preparation method for an indium tin oxide thin film in an embodiment of the present invention. The preparation method comprises:

providing an indium oxide target material, a tin target material, and a matrix, which are discrete, in a depositing chamber;

generating oxygen particles and indium particles from a target surface of the indium oxide target material while generating tin particles from a target surface of the tin target material; and

depositing the oxygen particles, the indium particles, and the tin particles on a surface of the matrix to form an indium tin oxide thin film.

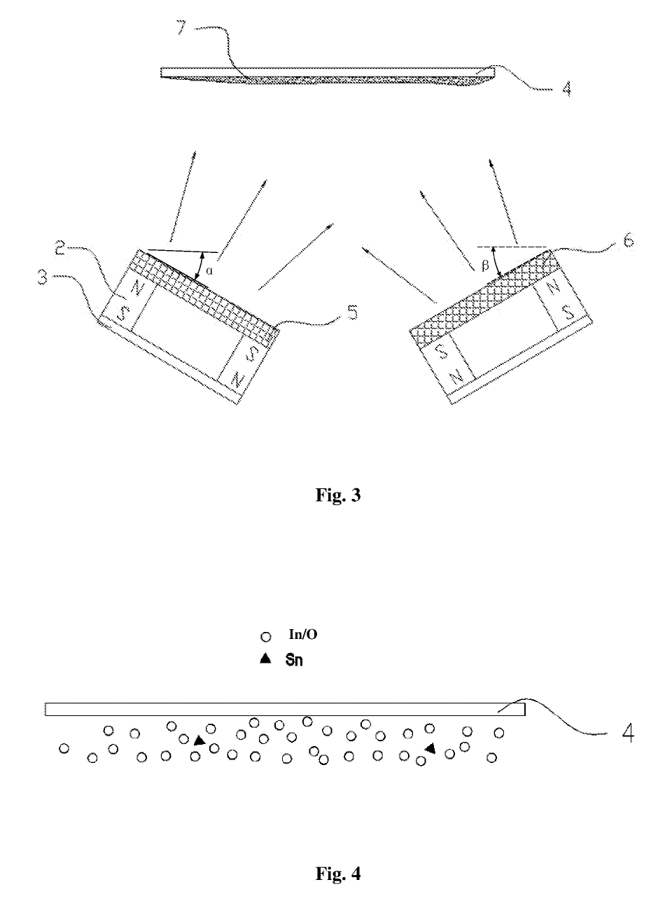

The indium oxide target material and the tin target material which are discrete refer to the indium oxide target material and the tin target material are individually prepared and mounted on different target material substrates. With reference to those as shown in FIG. 3, the indium oxide target material 5 and the tin target material 6 are respectively mounted on different target material jackets. The target material jacket is composed of a target material substrate 3 at the bottom and a magnetic core 2 above the substrate.

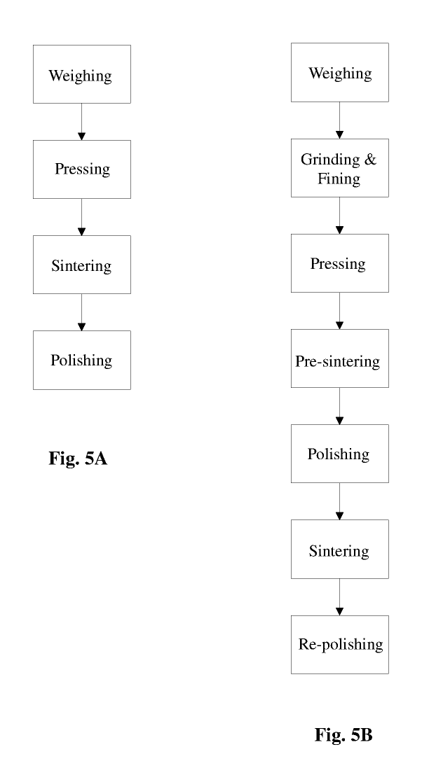

The two target materials may be prepared by the same or different preparation method(s). The preparation of the indium oxide target material may be performed in a manner of metal oxide sintering. This manner may comprise weighing an appropriate amount of indium oxide powder and further subjecting the powder to pressing, pre-sintering, polishing, sintering, and re-polishing. Furthermore, since it is not required to mix various powders, a plurality of intermediate steps may also be omitted. After weighing the indium oxide powder, the indium oxide powder is directly subjected to pressing, sintering, and polishing, and the process flow thereof can be seen in FIG. 5A. This mode omits a plurality of procedures compared to a conventional multi-component target material process. A conventional preparation process can be seen in FIG. 5B, a plurality of process steps are desired to be undergone, such as weighing→grinding and fining→pressing→pre-sintering→polishing→sintering→re-polishing, etc. Furthermore, with respect to the preparation of the tin target material, a molded tin target material may be obtained by conventional preparation in a manner of powder metallurgy, or may be directly obtained in a manner of mechanical processing. In the process of the preparation of various indium tin oxide thin-films, this tin target material is not required to be detached halfway, unless the target material is depleted and needs to be replaced.

With respect to the size selection of the target material, it may be designed to have the same target surface; or it may be designed according to the atomic ratio of indium and tin practically needed. For example, if the practically desired atomic ratio of indium and tin in the indium tin oxide thin film is 20:1, then the target surface area of the indium oxide target material is designed to be greater than the target surface area of the tin target material, and preferably, the former is 10-20 times the latter.

Furthermore, if there is a demand for adjusting magnetic properties or photoelectric properties of the indium tin oxide thin film, other elements are generally desired to be doped in the indium tin oxide thin film, and elements may also be doped in the corresponding target material. If there is a demand for magnetic properties of the indium tin oxide thin film, one or more magnetic elements, such as Co, Fe, etc., may be doped in the indium oxide target material. The doping proportions of the one or more magnetic elements are between about 0.5% and 2.5% (percent by mass), based on the total weight of the doped target material. If there is a demand for adjusting photoelectric properties of the indium tin oxide thin film, one or more metal elements, such as Al, Cu, etc., may be doped in the indium oxide target material. The doping proportions of the one or more metal elements are between about 1% and 5%, based on the total weight of the doped target material. In a particular process, when doping is desired, a pure indium oxide target material is replaced, and a prepared indium oxide target material doped with other elements is put to a position where the pure indium oxide target material is originally located, and a deposition process is restarted. With respect to the preparation method for an indium oxide target material doped with other elements, it may be performed according to a conventional preparation manner of mixing target materials, and verbose words are omitted herein.

Either or both of the tin target material or the indium oxide target material may be selected to be doped. Preferably, it is possible to dope the indium oxide target material only. In this way, the tin target material is not required to be replaced in the whole process of deposition (before and after adjusting the indium tin oxide thin film), and only the indium oxide target material is required to be replaced with a doped target material. It not required to prepare a new ITO target material by proportioning, grinding, sintering, and polishing again to purchase a new ITO target material, which saves the cost of study and may greatly save the preparation time of samples.

Also, as an alternative option, a target material may be further individually prepared from an element to be doped (forming a doping element target material) and is placed in a deposition chamber. When doping is not desired, this target material is not used for deposition (in a manner of shielding, etc.), and when doping is desired, a power is applied to this target material, and at the meanwhile a multi-target material process is performed in conjunction with the indium oxide target material and the tin target material to carry out the a co-deposition step.

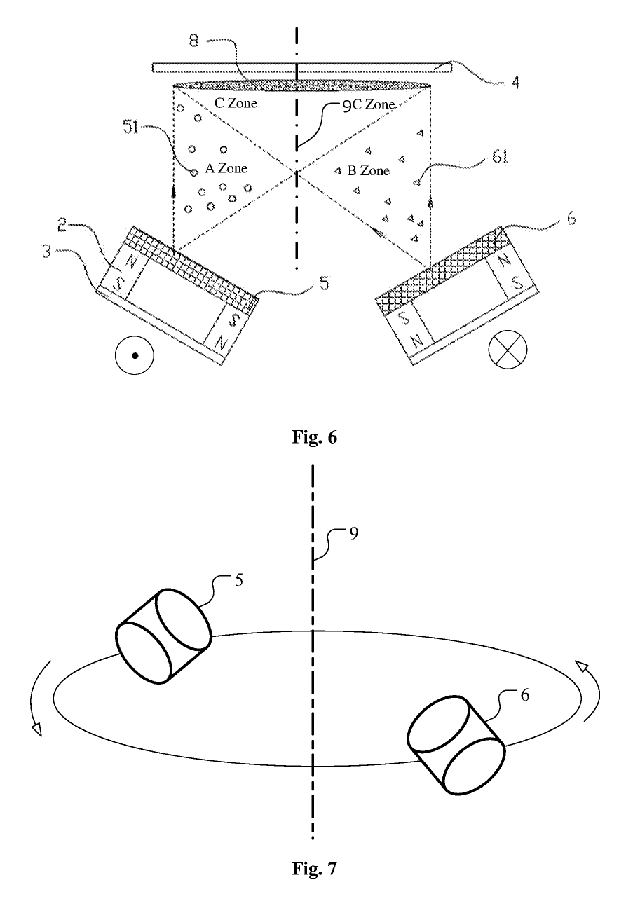

A manner of deposition in an embodiment of the present invention is magnetron sputtering. With reference to those as shown in FIG. 3, FIG. 4, and FIG. 6, in the process of sputtering, electrons in the vacuum chamber allow oxygen particles/indium particles 51 (possibly, oxygen ions/atoms and indium ions/atoms or a combination thereof) and tin particles 52 (tin atoms/ions) respectively to be sputtered out of two discrete target materials (the indium oxide target material 5 and the tin target material 6) in a manner of sputtering. These particles fly to the surface of the matrix 4, on which they are to be deposited, and a mixed oxygen-indium-tin plasma 8 is formed on the surface of the matrix 4 and is then deposited on the matrix 4 to form an indium tin oxide thin film 7.

Other than magnetron sputtering, various conventional manners of sputtering in the art may also be used.

When deposition is performed by using dual magnetron sputtering, the content of tin in the indium tin oxide thin film may be adjusted by adjusting the working power P1 loaded to the indium oxide target material and/or the working power P2 loaded to the tin target material. Particularly for practical applications of indium tin oxide thin-films, when the original atomic ratio of indium and tin in a indium tin oxide thin film cannot satisfy desired photoelectric properties, one means is to replace the sputtering target material, i.e., to adjust the atomic ratio of indium and tin in the sputtering target material; the other means is a means used in one embodiment of the present invention, which is to adjust the working power applied to the target material containing tin and indium in the sputtering process. For example, if the content of tin in the indium tin oxide is desired to be improved, the working power P2 of the tin target material may be improved alone, or the working power P1 of the indium oxide target material may be reduced alone, or the both may be implemented at the same time.

Preferably, the working power P1 loaded to the indium oxide target material and the working power P2 loaded to the tin target material satisfies P1/P2=10:1-20:1 and P1 is greater than the sputtering threshold of the indium oxide target material and P2 is greater than the sputtering threshold of the metal tin target material. For example, when a thin film having an atomic ratio of indium and tin of 20:1 is desired to be obtained, in view of sputtering thresholds of different atoms (the sputtering threshold refers to the minimal energy of incident particles which is necessary to enable atoms in the target material to be sputtered and leave the target material, and is typically 10-30 eV), the power of the indium oxide target material 5 is maintained unchanged and the working power of the tin target material 6 is adjusted to be 1/10 of the indium oxide target material. Furthermore, if the sputtering efficiency is taken into account, it is also possible to maintain the original working power P2 of the tin target material 6 unchanged and adjust the working power P1 of the indium oxide target material 5 to be 10 times that of the tin target material. Due to the adjustment of the sputtering power, when 1 pure tin atom is deposited onto the matrix, 10 oxygen/indium atoms are deposited onto the matrix.

It is to be clear to the person skilled in the art that a multilayer film of indium tin oxide having different components may be prepared by adjusting the working power P1 loaded to the indium oxide target material and the working power P2 loaded to the tin target material at different stages in the whole process of deposition, which cannot be achieved by conventional methods.

Other than indirectly adjusting the atomic proportions of respective elements in the indium tin oxide thin film by adjusting the power, a corresponding effect may also be achieved by adjusting the target surface area of the target material. For example, if the content of tin in the indium tin oxide is desired to be improved, the target surface area of the tin target material may be improved alone, or the target surface area of the indium oxide target material may be reduced alone, or the both manners described above may be implemented at the same time. The target surface is the surface of the target material which generates sputtered particles in the process of sputtering.

With respect to the relationship between the atomic ratio of indium and tin and the photoelectric property, considerations may be made according to the effects of respective elements in conventional indium tin oxide thin-films. Since this does not belong to the inventive concept of the present invention, verbose words are omitted herein.

In the process of sputtering, exemplary process parameters may be as follows: a glass substrate is selected as a matrix, and preferably, this glass substrate may be plated with a layer of a metal film, a nonconductive layer, and a semiconductor layer by sputtering in advance; the degree of vacuum in a magnetron sputtering chamber is allowed to be up to 10⁻⁴ Pa by using a vacuum system, and further preferably, the degree of vacuum is up to 10⁻⁵ Pa or more; argon gas is selected as a process gas of sputtering; furthermore, in order to enable the deposited thin film to be crystallized in the process of sputtering, the matrix typically operates with heating, wherein tin atoms doped in indium oxide further diffuse under heating conditions to form an indium tin oxide ITO thin film, and the temperature of the matrix is 100-250° C. and a further preferable temperature is 150-200° C.

Also, with the rapid progress of vacuum thin film techniques, the monitoring of the deposition rate during the sputtering process may also be quantitatively controlled directly by an instrument at present. For example, the change in the thickness of a film layer is monitored by a film thickness monitor and the deposition thickness per unit time may be calculated in conjunction with the time of sputtering deposition, which may reflect a corresponding sputtering efficiency.

Another manner of deposition in an embodiment of the present invention is laser pulse deposition.

When dual pulsed laser deposition is used for deposition, a similar means of adjustment is used. In step B, the content of tin in the indium tin oxide thin film is adjusted by adjusting the power P1′ of laser irradiating the indium oxide target material and/or the power P2′ of laser irradiating the tin target material.

Corresponding process steps and process parameters may be set with reference to dual magnetron sputtering described above, and correspondingly, the working power of magnetron sputtering may be replaced by the power of laser. Details can be seen hereinbefore, and verbose words are omitted herein.

It is to be clear to the person skilled in the art that other that magnetron sputtering and pulsed laser deposition described above, other means of physical vapor deposition, such as evaporation, arc plasma coating, molecular beam epitaxy, etc., all of which are within the scope protected by the present invention, may also be used to prepare an indium tin oxide thin film, as long as discrete indium oxide and tin target materials are used to generate oxygen particles/indium particles and tin particles in a deposition chamber respectively at the same time from these two target materials and these particles form an indium tin oxide thin film on a matrix together.

As a further preferable process, the inclined angle of the target material and the rotation mode of the target material may also be further improved to enhance the effect of deposition and satisfy the requirements of various indium tin oxide thin-films. Specific descriptions are made respectively below with reference to accompanying drawings.

In order to improve the utilization of the target material to the maximal extent, each target holder of the two target materials tilts at a certain angle and faces to the matrix 4. With reference to those as shown in FIG. 3, the indium oxide target material 5 and the tin target material 6 are all provided on the side of the matrix where a thin film is to be deposited, wherein the included angle between the indium oxide target material 5 and the plane where the matrix 4 is located is α, the included angle between the tin target material 6 and the plane where the matrix 4 is located is β, wherein 0°<α<60° and 0°<β<60° and further preferably 40°<α<50° and 40°<β<50°.

With reference to those as shown in FIG. 6, during the sputtering process, oxygen particles/indium particles 51 generated from the indium oxide target material 5 by sputtering fly to the surface of the matrix, and the oxygen particles/indium particles 51 are mainly distributed in area A and area C, whereas tin particles 61 are generated from the tin target material 6 by sputtering, and the tin particles 61 are mainly distributed in area B and area C. These two types of particles are well mixed in area C, and thus a mixed oxygen-indium-tin plasma 8 is formed on the surface of the matrix 4 and is in turn deposited on the matrix 4. The sputtering angle of the two target materials corresponds to the angle of the matrix, and thus the target material may be fully used. If there is no included angle between the two target materials and the plane where the matrix is located, on one hand, it is difficult to ensure that the matrix planes to which the two target materials face are overlapped and the sputtered particles are unevenly distributed on the surface of the matrix, and on the other hand, a portion of the sputtering angle of the target material will be distributed outside the matrix 4, resulting in the waste of the target material.

Preferably, included angles α and β of the indium oxide target material 5 and the tin target material 6 with the plane are equal, and the two target materials may be provided on the same plane carrier, which is in parallel to the plane where the matrix 4 is located and is located below the matrix 4. Additionally, even further preferably, the indium oxide target material 5 and the tin target material 6 are symmetrically provided along the perpendicular bisector 9 (a straight line which is drawn from the geometric center of the surface of the matrix to be deposited and is perpendicular to the surface of the matrix to be deposited) of the matrix 4. This provision enables the two types of particles to be more evenly distributed on the surface of the matrix 4.

In order to further improve the evenness of the deposited indium tin oxide thin film, the target material may be rotated during deposition. In the process of rotation, oxygen particles/indium particles 51 and tin particles 61 are allowed to be distributed the inner space of a sputtering depositing chamber.

FIG. 7 is a schematic diagram of the rotation of an indium oxide target material and a tin target material in an embodiment of the present invention. Typically, the surface of the matrix 4 to be deposited is a regular pattern, which has a center point, a center line is drawn from this center point along the direction perpendicular to the surface of the matrix to be deposited. This center line is perpendicular to this surface to be deposited, and is also referred to as a perpendicular bisector 9.

A rotating disk is provided below the matrix, and the rotation surface of this rotating disk is in parallel to the surface to be deposited. the indium oxide target material 5 and the tin target material 6 are fixed on the rotating disk. The two target materials are symmetrically provided along the perpendicular bisector of the matrix, on the basis that a certain inclined angle with the surface of the matrix to be deposited is maintained. The two target materials may be rotated under the driving of the rotating disk with the perpendicular bisector 9 as an axis. Preferably, The rotation radii of the indium oxide target material 5 and the tin target material 6 are the same.

In conjunction with those as shown in FIG. 6 and FIG. 7, in order to improve the evenness of mixing, a combination of target material+magnetic core+substrate is set to perform circulating rotation motion in the direction as shown in the figures, wherein “⊙” indicates that the indium oxide target material 5 is rotated out of the section shown in FIG. 6 and “⊗” indicates that the tin target material is rotated into the section shown in FIG. 6. The process of sputtering coating is performed at the same time of motion. The rotation center of two combinations (each combination comprises a target material substrate, a magnetic core, and a target material) is the position of the center of the matrix 4 in the figure, i.e., the perpendicular bisector 9. By means of rotational mixing, and under the coaction of the original high-temperature diffusion, the evenness of the prepared indium tin oxide thin film is better ensured. Preferably, the rotation speed is 5-30 revolutions/minute.

Preferably, the rotation motion of the combination may be achieved by an electric motor or other digital-control means. During the sputtering process, the rotation speed of the electric motor may be controlled at any time. In the initial period of deposition, the rotation speed is relatively low (for example, 5-15 revolutions/minute). In the middle period of deposition, since sputtered particles are more, the rotation speed is increased (for example, 20-35 revolutions/minute). In the later period of deposition, the rotation speed is then reduced (5-15 revolutions/minute).

With reference to those as shown in FIG. 6 again, during the sputtering process, when rotation is not performed, oxygen particles/indium particles are mainly distributed in area A and tin particles are mainly distributed in area B, and after rotation, two types of particles are distributed in area A and area B. Therefore, particles in area C and the mixed oxygen-indium-tin plasma 8 are also mixed more uniformly, and thus the two types of particles deposited onto the matrix 4 also exhibit an effect of a more even film layer.

Preferably, according to a scheme for doping an indium oxide target material in a form described above, a target material composed of a doping element is desired to be provided. That is, co-deposition of three or more target materials is performed. The three target materials may be provided on a rotating disk with equal rotation radii or unequal rotation radii. When doping is not performed, the working power is not applied to the doped target material. When doping is desired, the working power is introduced to this target material. Therefore, a respective doping element is excited to generate sputtered doping particles, which then undergo the rotation of the rotating disk to be evenly distributed throughout a process chamber.

Specific processes of the preparation method of the indium tin oxide thin film are introduced above. By providing discrete target materials, compared to conventional preparation methods for preparing target materials having different tin contents by grinding and sintering in a manner of single target material coating, indium tin oxide thin-films having different compositions may be obtained with the same target materials by the preparation method in embodiments of the present invention, and the control over the content of tin in the thin film is more convenient and the cost of development is saved.

The indium tin oxide thin film in embodiments of the present invention and the preparation method for this indium tin oxide thin film may have the following advantageous effects:

(1) a completely new preparation method for an indium tin oxide thin film is provided;

(2) an indium tin oxide thin film having different component proportions may be prepared from merely two target materials, so that the step for producing an indium tin oxide target material having different component proportions is omitted, the process efficiency is improved, and repeated production and waste of the target material are avoided, and at the meanwhile, the period of development is effectively shortened;

(3) in magnetron sputtering, the content of tin in the indium tin oxide thin film is adjusted by adjusting the working power P1 loaded to the indium oxide target material and/or the working power P2 loaded to the tin target material, so that the control method is simple and convenient and it becomes possible to prepare a multilayer film of indium tin oxide having different components;

(4) if element doping is desired, only the indium oxide target material is required to be replaced, and the tin target material is not required to be replaced in the process of during the whole process, so that some process steps are omitted;

(5) various demands for adjusting magnetic properties or photoelectric properties of the indium tin oxide thin film are satisfied by the doping of the target material;

(6) the utilization of the target material is improved by providing an inclined angle between the target material and the surface of the matrix to be sputtered; and

(7) in order to improve the evenness of mixing, the target material is rotated so as to improve the uniformity of the deposition of the film layer.

By preparing an indium oxide target material and a tin target material, which are discrete, in the preparation method of the present invention, repeated preparation of target materials may be avoided, and the sputtering process is not required to be restarted (for example, the vacuum chamber is not required to be re-opened halfway). Compared to conventional preparation methods for preparing target materials having different tin contents by grinding and sintering in a manner of single target material coating, the cost of development is saved, the period of development is effectively shortened, and it is more convenient to control the content of tin in the thin film. The preparation method may be used in the production of various display apparatuses.

Based on the same inventive concept, there is further provided an indium tin oxide thin film obtained by using the above preparation method for a indium tin oxide thin film.

Preferably, the indium tin oxide thin film is a product used in a thin film of a liquid crystal panel. Before the deposition of the indium tin oxide thin film, a metal film and a nonconductive layer are first sequentially plated on a glass substrate, and an indium tin oxide (ITO) thin film is then prepared by the preparation method described above.

Furthermore, according to the properties of the indium tin oxide thin film desired to be exhibited, the ratio of indium and tin or the doping element is required to be adjusted correspondingly, which may be achieved by the method introduced above. Therefore, in this embodiment, there may be various indium tin oxide thin-films which exhibit differently in terms of photoelectric properties (such as transmittance, carrier mobility, and dislocation density) and magnetic properties.

Based on the same inventive concept, there is further provided an array substrate, comprising a substrate; and an indium tin oxide thin film described above is deposited on the substrate.

Typically, the array substrate comprises a glass substrate, a gate line and gate electrode layer formed on the glass substrate, a gate insulating layer formed on the gate line and gate electrode layer, an active layer, a first transparent conductive layer formed from the indium tin oxide thin film described above, and a source electrode formed on the gate insulating layer, a passivation layer formed on the source electrode, and a second transparent conductive layer formed on the passivation layer.

A typical manufacture of an array substrate comprises forming an active layer on a glass substrate for preparing an array substrate, depositing the indium tin oxide thin film described above on this glass substrate, and forming a first transparent conductive layer by a mask procedure; and depositing a metal thin film on the glass substrate having the first transparent conductive layer formed thereon, and forming a source electrode of a TFT by a corresponding mask procedure.

Based on the same inventive concept, there is further provided a display apparatus. The means for providing the display apparatus is assembling the array substrate described above as a component therein into a display apparatus according to a conventional assembly means.

A conventional assembly means may be: (1) providing a color filter substrate, and preparing a substrate spacer column on the color filter substrate according to the method in embodiments of the present invention; (2) subjecting the array substrate and the color filter substrate to a cell-aligning process to form a liquid crystal cell; and (3) filling a liquid crystal material in the gap between the array substrate and the color filter substrate to produce a display apparatus.

The display apparatus may be any product or member having the function of display, such as a cell phone, a tablet computer, a television, a display, a laptop, a digital photo frame, a navigator, etc.

Furthermore, this document may set examples of parameters comprising specific values, but these parameters are not required to be equal to corresponding values and are approximate to corresponding values in an acceptable error tolerance or design constraint. Directional words mentioned in embodiments, for example “upper”, “lower”, “front”, “rear”, “left”, “right”, etc., are merely with reference to the direction in the accompanying drawings, but are not intended to limit the scope protected by the present invention. Furthermore, unless the steps are particularly described or must occur sequentially, the order of the steps described above is not limited to those described above, and may be changed or rearranged according to the desired design.

Objects, technical solutions, and advantageous effects of the present invention are further illustrated in details by the specific embodiments described above. It is to be understood that those described above are merely specific embodiments of the present invention, but are not intended to limit the present invention. All of modifications, equivalent replacements, improvements, and the like, which are within the spirit and the principle of the present invention, should be encompassed in the scope protected by the present invention.

1. A preparation method for an indium tin oxide thin film, comprising:
providing an indium oxide target material, a tin target material, and a matrix, which are discrete, in a depositing chamber;
generating oxygen particles and indium particles from a target surface of the indium oxide target material while generating tin particles from a target surface of the tin target material; and
depositing the oxygen particles, the indium particles, and the tin particles on a surface of the matrix to form the indium tin oxide thin film.

2. The preparation method for an indium tin oxide thin film according to claim 1, wherein oxygen particles and indium particles are generated from the target surface of the indium oxide target material while tin particles are generated from the target surface of the tin target material by magnetron sputtering, pulsed laser deposition, evaporation, arc plasma coating, or molecular beam epitaxy.

3. The preparation method for an indium tin oxide thin film according to claim 2, wherein oxygen particles and indium particles are generated from the target surface of the indium oxide target material while tin particles are generated from the target surface of the tin target material by magnetron sputtering, and the magnetron sputtering comprises dual magnetron sputtering; and
wherein tin content in the indium tin oxide thin film is adjusted by adjusting working power P1 loaded to the indium oxide target material and/or working power P2 loaded to the tin target material.

4. The preparation method for an indium tin oxide thin film according to claim 3, wherein the working power P1 loaded to the indium oxide target material and the working power P2 loaded to the tin target material satisfies P1/P2=10:1-20:1 and P1 is greater than a sputtering threshold of the indium oxide target material and P2 is greater than a sputtering threshold of the tin target material.

5. The preparation method for an indium tin oxide thin film according to claim 2, wherein oxygen particles and indium particles are generated from the target surface of the indium oxide target material while tin particles are generated from the target surface of the tin target material by pulsed laser deposition, and the pulsed laser deposition comprises dual pulsed laser deposition; and
wherein tin content in the indium tin oxide thin film is adjusted by adjusting power P1′ of laser irradiating the indium oxide target material and/or power P2′ of laser irradiating the tin target material.

6. The preparation method for an indium tin oxide thin film according to claim 1, wherein tin content in the indium tin oxide thin film is adjusted by adjusting an area of the target surface of the indium oxide target material and/or an area of the target surface of the tin target material.

7. The preparation method for an indium tin oxide thin film according to claim 1, wherein the matrix is heated to a temperature between 100° C. and 250° C. during deposition.

8. The preparation method for an indium tin oxide thin film according to claim 1, wherein the indium oxide target material and the tin target material are provided on the same side of the matrix; and
wherein an included angle between the target surface of the indium oxide target material and the surface of the matrix is α, an included angle between the target surface of the tin target material and the surface of the matrix is β, and wherein 0°<α<60° and 0°<β<60°.

9. The preparation method for an indium tin oxide thin film according to claim 8, wherein the target surface of the indium oxide target material and the target surface of the tin target material are symmetrically provided relative to a perpendicular bisector of the matrix; and
wherein the perpendicular bisector passes through a center point of the surface of the matrix and is perpendicular to the surface of the matrix.

10. The preparation method for an indium tin oxide thin film according to claim 1, wherein:
the indium oxide target material and the tin target material are set to rotate with a perpendicular bisector of the matrix as an axis, and relative positions of the target surface of the indium oxide target material and the target surface of the tin target material are kept fixed during rotation; and
the perpendicular bisector passes through a center point of the surface of the matrix and is perpendicular to the surface of the matrix.

11. The preparation method for an indium tin oxide thin film according to claim 10, wherein the rotation has a rotation speed set to be 5-30 revolutions/minute.

12. The preparation method for an indium tin oxide thin film according to claim 1, wherein the indium oxide target material is a doped target material doped with a preset element.

13. The preparation method for an indium tin oxide thin film according to claim 12, wherein the preset element comprises one or more magnetic elements, wherein doping proportions of the one or more magnetic elements are between 0.5% and 2.5% based on a total weight of the doped target material.

14. The preparation method for an indium tin oxide thin film according to claim 12, wherein the preset element comprises one or more metal elements, wherein doping proportions of the one or more metal elements are between 1% and 5% based on a total weight of the doped target material.

15. The preparation method for an indium tin oxide thin film according to claim 1, wherein:
a discrete doping element target material is further provided in the depositing chamber; and
doping element particles are generated from the doping element target material, and form a doped indium tin oxide thin film on the surface of the matrix together with the oxygen particles, the indium particles, and the tin particles.

16. The preparation method for an indium tin oxide thin film according to claim 1, wherein the indium oxide target material is prepared in a manner of metal oxide sintering, and the tin target material is prepared in a manner of powder metallurgy.

17. An indium tin oxide thin film obtained by using the preparation method of claim 1.

18. An array substrate comprising the indium tin oxide thin film of claim 17.

19. The array substrate according to claim 18, further comprising:
a substrate; and
a gate line and gate electrode layer, a gate insulating layer, and an active layer, which are sequentially deposited on the substrate;
wherein the substrate, on which the gate line and gate electrode layer, the gate insulating layer, and the active layer have been deposited, is used as the matrix, and the indium tin oxide thin film is deposited on the matrix.

20. A display apparatus comprising the array substrate of claim 18.
